(19) United States
(12) Patent Application Publication
(10) Pub. No.: US 2024/0224447 A1
(43) Pub. Date: Jul. 4, 2024

(54) DESIGN STRUCTURE OF MACHINE-WASHABLE TEMPERATURE CONTROLLER

(71) Applicants: MEC ADDHEAT (KAIPING) CO. LTD., Kaiping City (CN); SainStore Technology Co., Ltd, Dongguan (CN)

(72) Inventors: CHIENCHOU CHEN, Kaiping City (CN); Tianle Cheng, Dongguan (CN); Liping Huang, Dongquan (CN)

(21) Appl. No.: 18/603,528

(22) Filed: Mar. 13, 2024

(30) Foreign Application Priority Data
Jan. 4, 2024 (CN) 202410013657.5

(51) Int. Cl. H05K 5/02; H05K 7/14

(52) U.S. Cl. CPC H05K 5/0217; H05K 7/1427

(57) ABSTRACT

The present disclosure provides a design structure of a machine-washable temperature controller, to highly integrate a waterproof design and improve structure stability. The design includes a temperature controller body. The temperature controller body includes a silicone shell having a concave cavity. A PCBA board is disposed in the concave cavity of the silicone shell. The design is unique in that a silicone support plate without a retaining wall board and a webbing-type electronic wire are provided. Strengthening and waterproofing of the overall structure are implemented through silicone with a specific viscosity. The webbing-type electronic wire is connected through a wiring slot notch, and a key portion is processed through a gum dipping technology, to enhance waterproof effect. After silicone for surface waterproof encapsulation is cooled, the overall structure becomes a rugged and sealed one-piece structure. This ensures stability and reliability in a laundry process, and provides an efficient and reliable solution for temperature control in a machine laundry environment of heating clothes. In this innovative technology, the PCBA board has better sealing effect and better effect on resistance to machine washing torque without a wiring structure, showing a broad application prospect.

### TECHNICAL FIELD

The present disclosure relates to the technical field of heating clothes, and in particular to a design structure of a machine-washable temperature controller.

### BACKGROUND

A machine-washable temperature controller is a temperature controller for heating clothes. Because the heating clothes are under a category of clothing, there is a significant necessity to wash the heating clothes by using a machine such as a washing machine.

Firstly, washing helps to keep the clothing clean. The heating clothes or daily clothes are inevitably stained with dirt, sweat, and bacteria after being dressed. These stains may be effectively removed by washing thoroughly, so that clothes are clean, and people feel more comfortable after dressing up the clothes.

Secondly, service life of the heating clothes can be significantly extended by taking proper cleaning and maintenance measures. Washing in the washing machine can effectively remove stains and bacteria from the clothes, to prevent the stains and bacteria from further penetrating and damaging fibers of the clothes. Therefore, a user can enjoy the warmth of the heating clothes for a longer period of time, and helps to reduce waste and lower negative impact on the environment.

In the prior art, as shown in FIG. 1, a temperature controller body 1 used in wearable heating clothes includes a silicone shell 3 having a concave cavity. A PCBA board is fastened in the concave cavity of the silicone shell 3, and a wiring slot notch that is connected to the concave cavity is disposed on a side of the silicone shell 3. After incoming and outgoing lines 11 of a power supply are placed into the concave cavity of the silicone shell through the notch and welded with the PCBA board, and waterproof encapsulation is performed through a liquid silicone material (Silicone Sealing Material) for the concave cavity opening.

In this case, because same materials have similar physical and chemical properties, for example, a shaped silicone shell and liquid silicone have similar physical and chemical properties, such as elasticity, stability, and chemical resistance. Therefore, when being connected, the same materials have good compatibility, to ensure reliability of sealing effect, and facilitate machine washing.

However, in this case, although the temperature controller body 1 may achieve better sealing effect in cooperation with the silicone shell through the liquid silicone, to achieve better sealing effect with the liquid silicone, insulating sleeves for the incoming and outgoing lines of the power supply may be made of silicone only, to make use of the similar physical and chemical properties of the same material. Therefore, there is better sealing effect between the incoming and outgoing lines 11 of the power supply and the temperature controller body 1.

However, this manner has a new problem. That is, although the silicone may achieve better sealing effect, wear resistance is relatively poor. During machine washing, due to stirring of the machine, the incoming and outgoing lines 11 of the power supply bear a relatively large force, and are easy to break. To avoid non-durability of a structure due to insulating sleeves that are made of a silicone material and that are used in the incoming and outgoing lines of the power supply, usually, the insulating sleeves that are made of a silicone material may be used in incoming and outgoing lines of the power supply close to only the temperature controller body 1. That is, incoming and outgoing lines of the power supply that are made of the silicone material are made shorter, and a wire body 12 of another insulating sleeve with higher resistance to a mechanical strength is wired with the incoming and outgoing lines 11 of the power supply. Therefore, based on a characteristic that a junction of the two wires 13 are relatively easy to firmly seal, when good sealing effect of the temperature controller is ensured, the incoming and outgoing lines 11 of the power supply and connected parts are effectively sealed, and relatively strong and durable.

However, in this manner, a wiring structure is needed to be used, a structure is more complex, and there are a plurality of connections.

Therefore, when the temperature controller is sealed with silicone liquid, a technical problem to be resolved by the present disclosure is to implement soundness and durability, reduce structural complexity, and ensure sealing effect of the incoming and outgoing lines of the power supply.

### SUMMARY

In view of the above technical problems in the prior art, the present disclosure is intended to provide a design structure of a machine-washable temperature controller, to resolve problems that the structural complexity is not easy to reduce and the sealing effect of the incoming and outgoing lines of the power supply is not easy to generate while the temperature controller is sealed with liquid silicone in background.

To solve the above technical problems, the present disclosure adopts the following technical solutions: A design structure of a machine-washable temperature controller includes a temperature controller body, where the temperature controller body includes a silicone shell having a concave cavity, a PCBA board is disposed in the concave cavity of the silicone shell, and a wiring slot notch that is connected to the concave cavity is disposed on a side of the silicone shell.

The design structure of a machine-washable temperature controller further includes a silicone support plate, a webbing-type electronic wire, and silicone for surface waterproof encapsulation.

The silicone support plate is disposed at a position on the silicone shell close to the wiring slot notch.

The webbing-type electronic wire includes one end, and a gum dipping portion is disposed at a position on the webbing-type electronic wire close to the one end.

The one end of the webbing-type electronic wire is placed into the concave cavity of the silicone shell through the wiring slot notch, to be electrically connected to the PCBA board, and to enable the gum dipping portion to be disposed in the concave cavity of the silicone shell and/or is disposed on an upper side of the silicone support plate.

The concave cavity of the silicone shell is provided with a concave cavity opening.

The silicone for surface waterproof encapsulation is separately filled in the concave cavity opening of the silicone shell, the wiring slot notch, and the upper side of the silicone support plate for waterproof encapsulation, to enable gum dipping portions of the silicone shell, the silicone support plate, and the webbing-type electronic wire to form a one-piece structure after the silicone for surface waterproof encapsulation is cooled.

As a further solution of the present disclosure, the silicone for surface waterproof encapsulation is silicone with a viscosity more than 10 Pa·s.

As a further solution of the present disclosure, the gum dipping portion of the webbing-type electronic wire is formed after being dipped in a silicone material having a high fluidity and a viscosity less than 0.1 Pa·s.

As a further solution of the present disclosure, a length of the gum dipping portion is more than 5 mm.

As a further solution of the present disclosure, the design structure of a machine-washable temperature controller further includes a transparent film, where the transparent film is disposed at a bottom of the concave cavity, and the PCBA board is placed in the concave cavity through the transparent film.

As a further solution of the present disclosure, the silicone shell and the silicone support plate are a one-piece structure.

A design method for a machine-washable temperature controller is provided. The method includes the following steps.

Step 1: Determine a position and length of a gum dipping portion of a webbing-type electronic wire based on a length of a silicone support plate on a silicone shell, where decision criteria for the position and length of the gum dipping portion are that the gum dipping portion does not extend outside the silicone support plate after the webbing-type electronic wire is electrically connected to a PCBA board.

Step 2: Bend an end, electrically connected to the PCBA board, of the webbing-type electronic wire, to form a bending portion; dip the bending portion in a liquid silicone material to form the gum dipping portion; and enable the gum dipping portion to be immediately drawn, by the webbing-type electronic wire, into a gap between a fiber and a copper wire.

As a further solution of the present disclosure, the liquid silicone material in step 2 is a silicone material having a high fluidity and a viscosity less than 0.1 Pa·s.

A design method for a machine-washable temperature controller is provided. The method includes the following steps.

Step 1: Provide a temperature controller body, where the temperature controller body includes a silicone shell having a concave cavity, and the concave cavity includes a concave cavity opening.

Step 2: Dispose a PCBA board in the concave cavity of the silicone shell.

Step 3: Provide, on a side of the silicone shell, a wiring slot notch that is connected to the concave cavity.

Step 4: Provide a silicone support plate, a webbing-type electronic wire, and silicone for surface waterproof encapsulation.

Step 5: Dispose the silicone support plate at a position on the silicone shell close to the wiring slot notch.

Step 6: Place one end of the webbing-type electronic wire into the concave cavity of the silicone shell through the wiring slot notch, electrically connect the one end of the webbing-type electronic wire to the PCBA board, and ensure that a gum dipping portion is disposed at a position on the webbing-type electronic wire close to the one end, and the gum dipping portion is disposed in the concave cavity of the silicone shell and/or is disposed on an upper side of the silicone support plate.

Step 7: Fill the silicone for surface waterproof encapsulation in the concave cavity opening of the silicone shell, the wiring slot notch, and the upper side of the silicone support plate for waterproof encapsulation, to enable gum dipping portions of the silicone shell, the silicone support plate, and the webbing-type electronic wire to form a one-piece structure after the silicone for surface waterproof encapsulation is cooled.

As a further solution of the present disclosure, the method further includes the following steps:

Step 8: Take silicone with a viscosity more than 10 Pa·s as the silicone for surface waterproof encapsulation.

Step 9: Perform dipping in a silicone material having a high fluidity and a viscosity less than 0.1 Pa·s, to form the gum dipping portion of the webbing-type electronic wire; and before the gum dipping portion is connected to the temperature controller body, take the gum dipping portion as a waterproofing measure used to prevent water from entering.

Step 10: Ensure that a length of the gum dipping portion is more than 5 mm.

Step 11: Place a transparent film at a bottom of the concave cavity, and place the PCBA board in the concave cavity through the transparent film.

Step 12: Enable the silicone shell and the silicone support plate to be a one-piece structure.

Compared with conventional technologies, the present disclosure has the following beneficial effects: Highly integration of a waterproof design and improvement of structure stability are implemented. The design includes a temperature controller body. The temperature controller body includes a silicone shell having a concave cavity. A PCBA board is disposed in the concave cavity of the silicone shell. The design is unique in that a silicone support plate without a retaining wall board and a webbing-type electronic wire are provided. Strengthening and waterproofing of the overall structure are implemented through silicone with a specific viscosity. The webbing-type electronic wire is connected through a wiring slot notch, and a key portion is processed through a gum dipping technology, to enhance waterproof effect. After silicone for surface waterproof encapsulation is cooled, the overall structure becomes a rugged and sealed one-piece structure. This ensures stability and reliability in a laundry process, and provides an efficient and reliable solution for temperature control in a machine laundry environment of heating clothes. In this innovative technology, the PCBA board has better sealing effect and better effect on resistance to machine washing torque without a wiring structure, showing a broad application prospect.

Additional aspects and advantages of the present disclosure will be partly provided in the following description, and partly become evident in the following description or understood through the practice of the present disclosure.

### BRIEF DESCRIPTION OF THE DRAWINGS

To describe the technical solutions in the embodiments of the present disclosure or in the prior art more clearly, the accompanying drawings required for describing the embodiments or the prior art will be described briefly below. Apparently, the accompanying drawings in the following description show some embodiments of the present disclosure, and a person of ordinary skill in the art may still derive other drawings from these accompanying drawings without creative efforts.

FIG. 1 is a schematic diagram of a wiring structure in a conventional technology;

FIG. 2 is a schematic diagram of an existing silicone support plate of an enormous silicone shell being a structure of a retaining wall board;

FIG. 3 is a schematic diagram of a structure affecting incoming and outgoing lines of a power supply from gently swinging due to presence of a hard retaining wall board when a silicone support plate with a retaining wall board is bent in a direction of an arrow A;

FIG. 4 is a schematic diagram of a structure of a side structure when a retaining wall board presents;

FIG. 5 is a schematic diagram of a structure when the retaining wall board is removed based on FIG. 4;

FIG. 6 is a schematic diagram of a structure when a webbing-type electronic wire is fitted with FIG. 5;

FIG. 7 is a schematic diagram of a structure that an outgoing line position is more flexible and soft due to the design of a silicone support plate without a retaining wall board during bending in FIG. 6;

FIG. 8 is an exploded view of a structure of the present disclosure;

FIG. 9 is a schematic diagram of a structure that facilitates a webbing-type electronic wire to flexibly swing in a direction of an arrow B;

FIG. 10 is a schematic diagram of a structure of a temperature controller body in a cross-sectional state according to the present disclosure;

FIG. 11 is a schematic diagram of a structure that gaps between man-made fiber braided straps and gaps between enameled copper wires are full before waterproof processing is performed on a webbing-type electronic wire; and

FIG. 12 is a schematic diagram of a structure that gaps between man-made fiber braided straps and gaps between enameled copper wires are filled with a silicone material less than 0.1 Pa·s and completely dipped in gum after waterproof processing is performed.

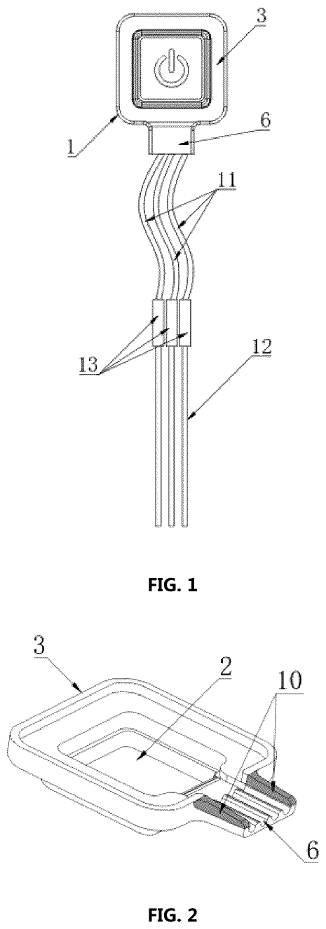

### REFERENCE NUMERALS

temperature controller body 1, concave cavity 2, silicone shell 3, PCBA board 4, wiring slot notch 5, silicone support plate 6, webbing-type electronic wire 7, silicone for surface waterproof encapsulation 8, transparent film 9, retaining wall board 10, incoming and outgoing lines 11 of power supply, wire body 12, junction 13, gum dipping portion 14, another side 15, button 16, man-made fiber braided strap 17, enameled copper wire 18, gap 19.

### DETAILED DESCRIPTION OF THE EMBODIMENTS

The technical solutions in the embodiments of the present disclosure will be clearly and completely described below. Apparently, the described embodiments are merely a part of, not all of, the embodiments of the present disclosure. All other embodiments obtained by a person of ordinary skill in the art based on embodiments of the present disclosure without creative efforts should fall within the protection scope of the present disclosure.

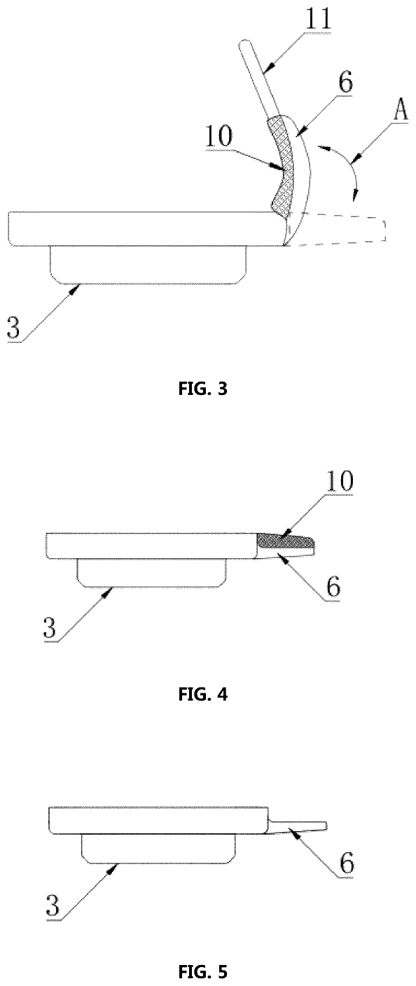

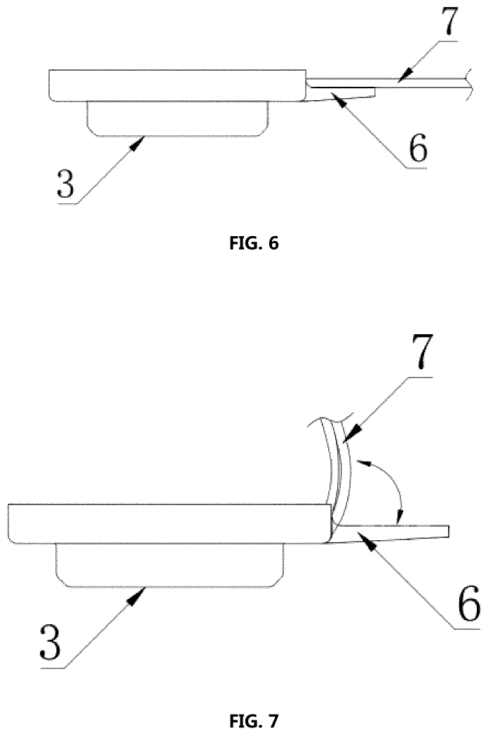

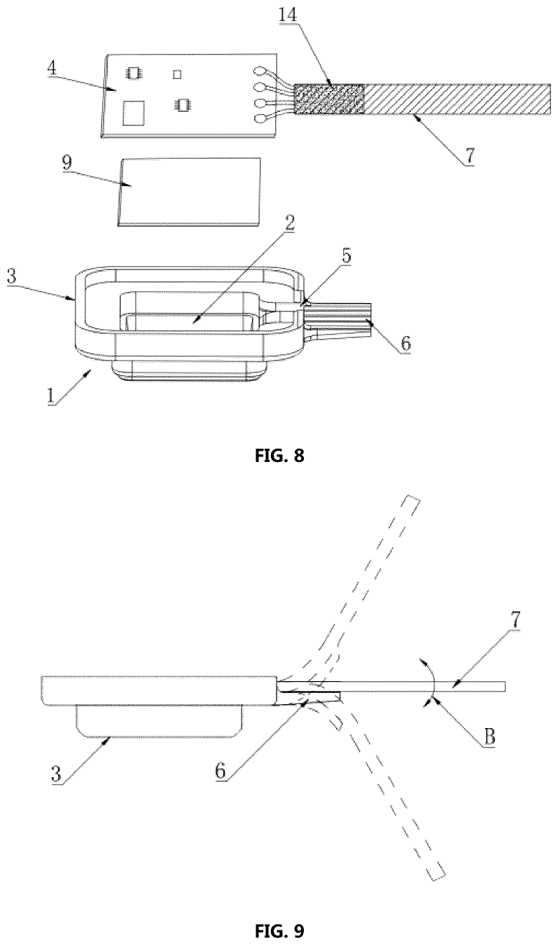

Referring to FIG. 2 to FIG. 12, in this embodiment, a design structure of a machine-washable temperature controller includes a temperature controller body 1. The temperature controller body 1 includes a silicone shell 3 having a concave cavity 2. A PCBA board 4 is disposed in the concave cavity 2 of the silicone shell 3, and a wiring slot notch 5 is disposed on a side, connected to the concave cavity 2, of the silicone shell 3.

The design structure of a machine-washable temperature controller further includes a silicone support plate 6, a webbing-type electronic wire 7, and silicone for surface waterproof encapsulation 8.

The silicone support plate 6 at a position on the silicone shell 3 close to the wiring slot notch 5. The silicone support plate 6 extends outward against the bottom of the wiring slot notch 5 for carrying the webbing-type electronic wire 7 from the wiring slot notch 5.

The webbing-type electronic wire 7 includes one end, and a gum dipping portion 14 is disposed at a position on the webbing-type electronic wire 7 close to the one end. Therefore, the webbing-type electronic wire 7 is easy to seal through the gum dipping portion 14, to prevent water from entering the temperature controller body 1 from the webbing-type electronic wire 7, so that strong sealing protection is provided for the temperature controller body 1 without a wiring structure in conventional technologies.

The one end of the webbing-type electronic wire 7 is placed into the concave cavity 2 of the silicone shell 3 through the wiring slot notch 5, to be electrically connected to the PCBA board 4, and to enable the gum dipping portion 14 to be disposed in the concave cavity 2 of the silicone shell 3 and/or is disposed on an upper side of the silicone support plate 6, so that the enable the gum dipping portion 14 and the silicone shell 3 form a sealed one-piece structure through the silicone for surface waterproof encapsulation 8.

Due to the silicone support plate 6, in the conventional technologies, a structure in which retaining wall boards 10 are disposed on left and right sides 2 of the silicone support plate 6 is simplified. In the conventional technologies, a reason to dispose the retaining wall boards 10 on the left and right sides 2 at a position of an outgoing line of the temperature controller is as follows: when silicone is encapsulated, silicone liquid does not flow around, a plurality of electronic wires can be enclosed together through the retaining wall boards 10, so that silicone can be fixed, without scattering. Because of enclosure of the retaining wall boards 10 on the left and right sides and fixing effect of silicone, strength is increased, and elasticity and bending are reduced, which affects softness of the webbing-type electronic wire, and indirectly affects the washing machine. As a result, probability of breaking the line is increased.

In the present disclosure, at the position of the outgoing line of the temperature controller, a retaining wall board 10 with a wall outlet slot is canceled, and changed into a flat tray-type silicone support plate 6. Silicone for surface waterproof encapsulation 8 made of a same material has similar physical and chemical properties such as elasticity, stability, and chemical corrosion resistance after being cooled. Therefore, compared to the conventional technologies, a bending position may be presented at a 90° angle, without affecting a force angle of the PCBA board, so that probability of protecting the outgoing line from being broken due to dispersion of the force is still maintained.

Specifically, the concave cavity 2 of the silicone shell 3 is provided with a concave cavity opening (not shown in figures). The silicone for surface waterproof encapsulation 8 is separately filled in the concave cavity opening of the silicone shell 3, the wiring slot notch 5, and the upper side of the silicone support plate 6 for waterproof encapsulation, to enable gum dipping portions 14 of the silicone shell 3, the silicone support plate 6, and the webbing-type electronic wire 7 to form a one-piece structure after the silicone for surface waterproof encapsulation 8 is cooled.

The silicone 8 for surface waterproof encapsulation is silicone with a viscosity more than 10 Pa·s, so that construction is easy to conduct. Therefore, the silicone for surface waterproof encapsulation 8 does not flow rapidly when being filled at a position to be sealed, to achieve use effect which is favorable for sealing during construction.

The gum dipping portion 14 of the webbing-type electronic wire 7 is formed after being dipped in the silicone material having a high fluidity and a viscosity less than 0.1 Pa·s, so that the silicone liquid completely permeates man-made fibers of the surface layer and enameled copper wires on the inner layer of the webbing-type electronic wire 7, to form a blocking gap and a sealed area. During washing of the washing machine, water outside of the temperature controller is completely blocked outside of the temperature controller, to ensure that no water seeps into the temperature controller along the webbing-type electronic wire, and prevent the PCBA board from being short-circuited due to ingress of water.

A length of the gum dipping portion 14 is more than 5 mm.

The design structure of a machine-washable temperature controller further includes a transparent film 9, where the transparent film 9 is disposed at a bottom of the concave cavity 2, and the PCBA board 4 is placed in the concave cavity 2 through the transparent film 9.

The silicone shell 3 and the silicone support plate 6 are a one-piece structure.

A design method for a machine-washable temperature controller is provided. The method includes the following steps.

Step 1: Determine a position and length of a gum dipping portion 14 of a webbing-type electronic wire 7 based on a length of a silicone support plate 6 on a silicone shell 3, where decision criteria for the position and length of the gum dipping portion 14 are that the gum dipping portion does not extend outside the silicone support plate 6 after the webbing-type electronic wire 7 is electrically connected to a PCBA board 4.

Step 2: Bend an end, electrically connected to the PCBA board 4, of the webbing-type electronic wire 7, to form a bending portion, and dip the bending portion in a liquid silicone material, to form the gum dipping portion, to facilitate the gum dipping portion to be immediately drawn, by the webbing-type electronic wire 7, into a gap between a fiber and a copper wire.

The liquid silicone material in step 2 is a silicone material having a high fluidity and a viscosity less than 0.1 Pa·s, to facilitate the gum dipping portion to be drawn, by the webbing-type electronic wire 7, into a gap between a fiber and a copper wire.

A design method for a machine-washable temperature controller is provided. The method includes the following steps.

Step 1: Provide a temperature controller body 1, where the temperature controller body includes a silicone shell 3 having a concave cavity 2, and the concave cavity 2 includes a concave cavity opening.

Step 2: Dispose a PCBA board 4 in the concave cavity 2 of the silicone shell 3.

Step 3: Provide, on a side of the silicone shell 3, a wiring slot notch 5 that is connected to the concave cavity 2.

Step 4: Provide a silicone support plate 6, a webbing-type electronic wire 7, and silicone for surface waterproof encapsulation 8.

Step 5: Dispose the silicone support plate 6 at a position on the silicone shell 3 close to the wiring slot notch 5.

Step 6: Place one end of the webbing-type electronic wire 7 into the concave cavity 2 of the silicone shell 3 through the wiring slot notch 5, electrically connect the one end of the webbing-type electronic wire 7 to the PCBA board 4, and ensure that a gum dipping portion 14 is disposed at a position on the webbing-type electronic wire 7 close to the one end, and the gum dipping portion 14 is disposed in the concave cavity 2 of the silicone shell 3 and/or is disposed on an upper side of the silicone support plate 6.

Step 7: Fill the silicone for surface waterproof encapsulation 8 in the concave cavity opening of the silicone shell 3, the wiring slot notch 5, and the upper side of the silicone support plate 6 for waterproof encapsulation, to enable gum dipping portions 14 of the silicone shell 3, the silicone support plate 6, and the webbing-type electronic wire 7 to form a one-piece structure after the silicone for surface waterproof encapsulation 8 is cooled.

The method further includes the following steps:

Step 8: Take silicone with a viscosity more than 10 Pa·s as the silicone 8 for surface waterproof encapsulation.

Step 9: Perform dipping in a silicone material having a high fluidity and a viscosity less than 0.1 Pa·s, to form the gum dipping portion 14 of the webbing-type electronic wire 7; and before the gum dipping portion is connected to the temperature controller body 1, take the gum dipping portion as a waterproofing measure used to prevent water from entering.

Step 10: Ensure that a length of the gum dipping portion 14 is more than 5 mm.

Step 11: Place a transparent film 9 at a bottom of the concave cavity 2, and place the PCBA board 4 in the concave cavity 2 through the transparent film 9.

Step 12: Enable the silicone shell 3 and the silicone support plate 6 to be a one-piece structure.

### Technical Points of the Present Disclosure are as Follows:

1. A temperature controller is conducive to waterproofing and machine laundry, without the wiring structure.
2. Special webbing structure: Characteristics of silicone sealing are needed when the temperature controller is close to a welding connection position, and waterproofing with a same material is performed on a welded end of a webbing, that is, after a position close to one end of the webbing is bent, the welded end of the webbing is dipped in liquid silicone of a same material, to disable water to enter the controller through fibers of the webbing.
2-1. The webbing-type electronic wire 7 is, in a flat shape, formed by integrating dozens of enameled copper wires through a man-made fiber weaving method.
2-2. The webbing-type electronic wire 7 includes a plurality of enameled wires having many gaps for air or water flow. Dozens or hundreds of man-made fiber filaments between which gaps exist are coated on an external part of the webbing-type electronic wire 7, to form a channel that is easy to be dipped with water.
2-3. A current temperature controller used for wearable clothes and the temperature controller in this embodiment are disposed at the upper side of the PCBA board 4, the incoming and outgoing lines of the power supply after the PCBA board 4 are welded with the incoming and outgoing lines of the power supply, and waterproof encapsulation is performed through a liquid silicone material (Silicone Sealing Material) at the upper side of the PCBA board 4. However, to facilitate construction and prevent the silicone material from spilling out along the edge, silicone with poor fluidity and a viscosity more than 10 Pa·s is taken as a sealing and waterproofing material. In the case of easy construction, the 10 Pa·s material may only form a protective layer on the outer surface of the seal, but does not penetrate the inner layer of the man-made fiber filaments of the webbing-type electronic wire 7. In a laundry process of the washing machine, water penetrates the man-made fibers of the webbing-type electronic wire 7 that is exposed outside the temperature controller, and flows into the PCBA board 4 from gaps between the enameled wires and gaps between the man-made fibers, resulting in faults such as short circuit or oxidation.
2-4. Therefore, in this design, a silicone material (Silicone Sealing Material) that is compatible with waterproof encapsulation on the temperature controller and whose viscosity is less than 0.1 Pa·s is coated on the webbing-type electronic wire 7 that is before the welding pad of the PCBA board 4. A coating length is at least more than 5 mm, and a coating width is less than 20 mm width, to enable the silicone liquid to penetrate man-made fibers of a surface layer and enameled copper wires on an inner layer of a webbing-type electronic wire within such range, to form a blocking gap and a sealed area. During washing of the washing machine, water outside of the temperature controller is completely blocked outside of the temperature controller, to ensure that no water seeps in the temperature controller, and ensure that PCBA board 4 is not short-circuited due to ingress of water.

(1) As shown in FIG. 11, before waterproof processing on the webbing-type electronic wire 7, there are gaps 19 between man-made fiber braided straps 17 and gaps between enameled copper wires 18.

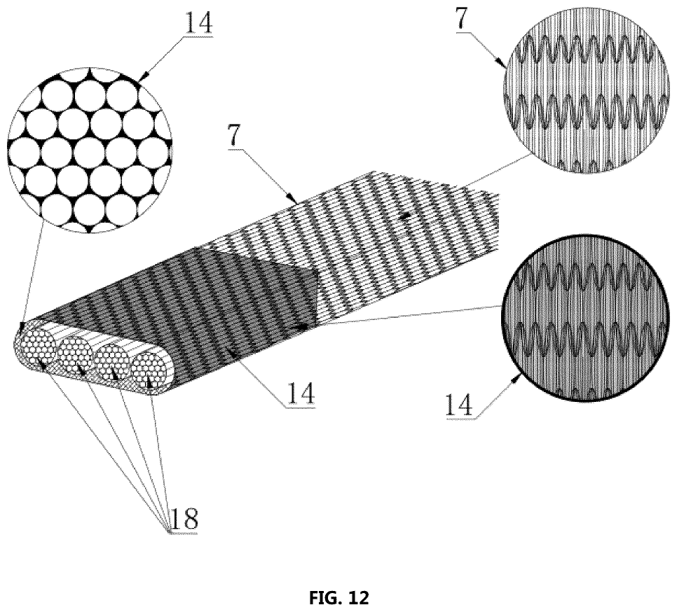

(2) As shown in FIG. 12, after waterproof processing, the gaps 19 between man-made fiber braided straps 17 and the gaps between enameled copper wires 18 are filled with a silicone material less than 0.1 Pa·s, and completely filled with gum.

### Embodiment 1

This embodiment provides a design structure of a machine-washable temperature controller. A main structure and implementations of the design structure of a machine-washable temperature controller are as follows:

Firstly, a temperature controller body 1 is provided. The temperature controller body 1 includes a silicone shell 3 having a concave cavity 2. A PCBA board 4 is disposed in the concave cavity 2, and a wiring slot notch 5 is disposed on a side, connected to the concave cavity 2, of the silicone shell 3.

Secondly, the silicone support plate 6 is disposed at a position on the silicone shell 3 close to the wiring slot notch 5. The silicone support plate 6 extends outward against the bottom of the wiring slot notch 5 for carrying the webbing-type electronic wire 7 from the wiring slot notch 5.

Then, the one end of the webbing-type electronic wire 7 is placed into the concave cavity 2 of the silicone shell 3 through the wiring slot notch 5, to be electrically connected to the PCBA board 4. A gum dipping portion 14 is disposed at a position on the webbing-type electronic wire 7 close to the one end. The gum dipping portion 14 of the webbing-type electronic wire 7 is formed after being dipped in the silicone material having a high fluidity and a viscosity less than 0.1 Pa·s, with a length more than 5 mm. This design enables the gum dipping portion 14 and the silicone shell 3 to form a sealed one-piece structure through the silicone for surface waterproof encapsulation 8.

Lastly, the silicone for surface waterproof encapsulation 8 whose viscosity is more than 10 Pa·s is filled in the concave cavity opening of the silicone shell 3, the wiring slot notch 5, and the upper side of the silicone support plate 6 for waterproof encapsulation, to enable gum dipping portions 14 of the silicone shell 3, the silicone support plate 6, and the webbing-type electronic wire 7 to form a one-piece structure after the silicone for surface waterproof encapsulation 8 is cooled.

In the foregoing embodiment, the design structure of the temperature controller can provide a strong sealing protection for the temperature controller body 1 without a wiring structure in conventional technologies. This prevents water from entering the temperature controller body 1 through the webbing-type electronic wire 7, so that the design structure of the temperature controller is suitable for machine laundry.

In specific implementations of the present disclosure:

### 1. Structure of Temperature Controller Body 1

Silicone shell 3: The silicone shell 3 having a concave cavity 2 is made of a silicone material that is highly elastic, abrasion-resistant, and ageing-resistant. The concave cavity 2 is delicately designed to accurately accommodate the PCBA board 4 and another key component.

PCBA board 4: carried in the concave cavity 2 of the silicone shell 3, and responsible for enabling core functions such as temperature control. The PCBA board 4 is highly integrated, to ensure efficient and stable temperature control in small space.

Wiring slot notch 5: located on a side of the silicone shell 3, and connected to the concave cavity 2, to facilitate wiring of the webbing-type electronic wire 7. The wiring slot notch 5 is tightly designed to minimize a size of the opening, to reduce a potential risk of water seepage.

### 2. Waterproof Enhanced Design

Silicone support plate 6: The silicone support plate 6 is disposed at a position on the silicone shell 3 close to the wiring slot notch 5. The support plate enhances structural strength of the wiring slot notch 5, and provides stable support for the webbing-type electronic wire 7, to prevent the webbing-type electronic wire 7 from loosening due to vibration in a laundry process.

Webbing-type electronic wire 7: A special webbing-type electronic wire 7 is used. A structure of special webbing-type electronic wire 7 has excellent resistance to abrasion and water resistance while ensuring flexibility of the wire. The one end of the electronic wire is accurately placed into the concave cavity 2 of the silicone shell 3 through the wiring slot notch 5, to be electrically connected to the PCBA board 4.

Gum dipping portion 14: A gum dipping technology is applied to a critical portion of the webbing-type electronic wire 7, and dipping is performed with a high viscosity silicone material that is compatible with the silicone shell 3. A length of the gum dipping portion 14 is accurately calculated and is at least more than 5 mm, to ensure excellent waterproofing effect under strong water flows of the washing machine.

3. Encapsulation with Liquid Silicone

Waterproof encapsulation: A professional encapsulation silicone for surface waterproofing 8 is used, with a viscosity more than 10 Pa·s. Complete waterproof encapsulation is performed for the concave cavity opening of the silicone shell 3, the wiring slot notch 5, and the upper side of the silicone support plate 6. Due to such encapsulation, after silicone 8 for surface waterproof encapsulation is cooled, the overall structure becomes a rugged and sealed one-piece structure.

Selection for materials: The selected encapsulation silicone 8 for surface waterproof has high viscosity, to ensure excellent encapsulation effect; and has excellent weather resistance and anti-aging properties, to ensure that waterproof performance does not deteriorate during long-term use.

### 4. Additional Features

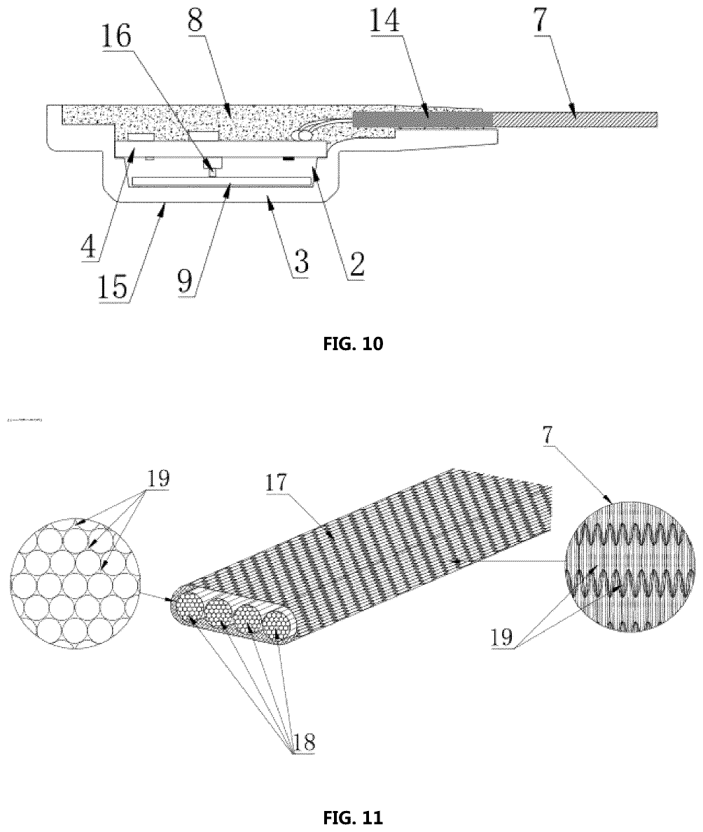

Transparent film 9: The transparent film 9 is placed at a bottom of the concave cavity 2, to facilitate a user to press another side 15 opposite to the bottom of the concave cavity 2 for temperature control, as shown in FIG. 10, a button 16 with a relatively small volume may be pressed by a transparent film 9 having specific hardness, and to avoid a pressing position on the button 16 from being limited due to the small volume.

The design structure of a machine-washable temperature controller provided in this embodiment ensures, in combination with advanced material science, accuracy manufacturing technologies, and innovative waterproof design, stability and reliability of the temperature controller under extreme laundry conditions, demonstrating a high integration, refinement, and excellent waterproof performance.

The design structure of a machine-washable temperature controller provided in the present disclosure, after careful consideration and design, a problem of water seepage of a conventional temperature controller in a laundry process is resolved, and excellent beneficial effect is demonstrated in various aspects. Detailed analysis is as follows:
1. Excellent waterproof performance: Due to design of innovative silicone support plate 6 and a gum dipping technology of the webbing-type electronic wire 7, this design implements multiple waterproof protection in the structure. The silicone support plate 6 enhances structural stability of the wiring slot notch 5, and effectively prevents, in long-term machine laundry, water from entering the PCBA board 4 along the webbing-type electronic wire 7. That is, the gum dipping portion 14 ensures that the electronic wire is completely sealed at a joint, and no water seeps even in the strong water flow. Such measures ensure absolutely waterproofing of the controller in a laundry process.
2. High integration and stability: A design that the PCBA board 4 is highly integrated reduces occupation of space, and improves accuracy and stability of control. In combination with excellent weather resistance and anti-aging properties of the silicone shell 3, it ensures that stable performance of the controller is maintained for a long period of time, and functions do not degrade due to environmental factors.
3. Wide application prospects: With the popularity of wearable devices, there is a growing demand for a temperature controller that can work properly in extreme environments such as laundry. Therefore, the market prospect is broad.
4. Enhancement on user experience: This design significantly improves the user experience by resolving a problem of damage to the controller encountered by the user in a laundry process. The user does not need to worry about damage to the controller due to water seepage, thereby enjoying a more convenient and carefree life.

In summary, the design structure of a machine-washable temperature controller provided in the present disclosure shows significant beneficial effect in terms of waterproof performance, stability, and user experience. This is not only an important improvement to the prior art, but also provides new ideas and directions for the development in related fields.

In the present disclosure, unless otherwise clearly specified, meanings of terms “installed”, “disposed”, “connected with”, “fastened to”, and “rotationally connected” should be understood in a board sense. For example, a connection may be a fixed connection, a removable connection, or an integral connection; may be a mechanical connection or an electrical connection; may be a direct connection or an indirect connection by using an intermediate medium; or may be intercommunication between two components or interaction between two components. Unless otherwise clearly specified, a person of ordinary skill in the art can understand a specific meaning of the term in the present disclosure based on a specific situation.

It is apparent for those skilled in the art that the present disclosure is not limited to details of the above exemplary embodiments, and that the present disclosure may be implemented in other specific forms without departing from the spirit or basic features of the present disclosure. The embodiments should be regarded as exemplary and non-limiting in every respect, and the scope of the present disclosure is defined by the appended claims rather than the above description. Therefore, all changes falling within the meaning and scope of equivalent elements of the claims should be included in the present disclosure.

1. A design structure of a machine-washable temperature controller, comprising a temperature controller body, wherein the temperature controller body comprises a silicone shell having a concave cavity, a PCBA board is disposed in the concave cavity of the silicone shell, and a wiring slot notch that is connected to the concave cavity is disposed on a side of the silicone shell;
the design structure of a machine-washable temperature controller further comprises a silicone support plate, a webbing-type electronic wire, and silicone for surface waterproof encapsulation;
the silicone support plate is disposed at a position on the silicone shell close to the wiring slot notch;
the webbing-type electronic wire comprises one end, and a gum dipping portion is disposed at a position on the webbing-type electronic wire close to the one end;
the one end of the webbing-type electronic wire is placed into the concave cavity of the silicone shell through the wiring slot notch, to be electrically connected to the PCBA board, and to enable the gum dipping portion to be disposed in the concave cavity of the silicone shell and/or is disposed on an upper side of the silicone support plate;
the concave cavity of the silicone shell is provided with a concave cavity opening; and
the silicone for surface waterproof encapsulation is separately filled in the concave cavity opening of the silicone shell, the wiring slot notch, and the upper side of the silicone support plate for waterproof encapsulation, to enable gum dipping portions of the silicone shell, the silicone support plate, and the webbing-type electronic wire to form a one-piece structure after the silicone for surface waterproof encapsulation is cooled.

2. The design structure of a machine-washable temperature controller according to claim 1, wherein the silicone for surface waterproof encapsulation is silicone with a viscosity more than 10 Pa·s.

3. The design structure of a machine-washable temperature controller according to claim 1, wherein the gum dipping portion of the webbing-type electronic wire is formed after being dipped in a silicone material having a high fluidity and a viscosity less than 0.1 Pa·s.

4. The design structure of a machine-washable temperature controller according to claim 3, wherein a length of the gum dipping portion is more than 5 mm.

5. The design structure of a machine-washable temperature controller according to claim 1, further comprising a transparent film, wherein the transparent film is disposed at a bottom of the concave cavity, and the PCBA board is placed in the concave cavity through the transparent film.

6. The design structure of a machine-washable temperature controller according to claim 1, wherein the silicone shell and the silicone support plate are a one-piece structure.
